(19) United States
(12) Patent Application Publication
(10) Pub. No.: US 2021/0296517 A1
(43) Pub. Date: Sep. 23, 2021

(54) INFRARED DETECTOR

(71) Applicants: SHARP KABUSHIKI KAISHA, Sakai City (JP); THE UNIVERSITY OF TOKYO, Tokyo (JP)

(72) Inventors: HIROFUMI YOSHIKAWA, Osaka (JP); YASUHIKO ARAKAWA, Tokyo (JP)

(21) Appl. No.: 17/198,992

(22) Filed: Mar. 11, 2021

(30) Foreign Application Priority Data
Mar. 23, 2020 (JP) 2020-051031

(51) Int. Cl. H01L 31/0304; H01L 31/0352; H01L 31/101; H01L 31/18

(52) U.S. Cl. CPC H01L 31/03046; H01L 31/035218; H01L 31/03042; H01L 31/101; H01L 31/1844; H01L 31/035236

(57) ABSTRACT

Provided is an infrared detector capable of achieving high sensitivity with little noise. An infrared detector includes: contact layers; a photoelectric conversion layer; a barrier layer; and an insertion layer. Each of the contact layers is doped with a dopant. The photoelectric conversion layer is placed between the contact layers, and includes a quantum layer (quantum dots) and an intermediate layer. The barrier layer is placed between the photoelectric conversion layer and one of the contact layers. The insertion layer is placed between, and in contact with, the photoelectric conversion layer and the one contact layer.

### CROSS-REFERENCE TO RELATED APPLICATION

The present application claims priority from Japanese Application JP2020-051031, the content of which is hereby incorporated by reference into this application.

### BACKGROUND OF THE INVENTION

### 1. Field of the Invention

The present invention relates to an infrared detector.

### 2. Description of the Related Art

Quantum Dot Infrared Photodetectors (QDIPs) hold high expectations as quantum infrared detectors to operate with high sensitivity, under high temperature, in quick response, and over a variety of wavelengths. Hence, research and development on the QDIPs is well underway.

Among the QDIPs, Non-Patent Literatures 1 and 2 propose ones including a single barrier layer made of AlGaAs whose Al composition is 0.3 and provided to one stacking side of the quantum dots, so that the QDIPs can operate with high sensitivity under high temperature (Non-Patent Literature 1: S. Chakrabarti, A. D. Stiff-Roberts, P. Bhattacharya, S. Gunapala, S. Bandara, S. B. Rafol, and S. W. Kennerly, “High-Temperature Operation of InAs—GaAs Quantum-Dot Infrared Photodetectors With Large Responsivity and Detectivity”, IEEE PHOTONICS TECHNOLOGY LETTERS, VOL. 16, 1361 (2004)), and Non-Patent Literature 2: S. Chakrabarti, A. D. Stiff-Roberts, X. H. Su, P. Bhattacharya, G. Ariyawansa and A. G. U. Perera, “High-performance mid-infrared quantum dot infrared photodetectors”, JOURNAL OF PHYSICS D: APPLIED PHYSICS 38, 2135(2005)). This single barrier layer is placed in contact with a contact layer.

### SUMMARY OF THE INVENTION

The single barrier layer, disclosed in Non-Patent Literatures 1 and 2 and made of AlGaAs, has an Al composition of 0.3. Hence, the single barrier layer has a defect level referred to as a DX center. The DX center is presumed to be produced by a significant lattice relaxation of a substitutional impurity serving as a donor. AlGaAs having an Al composition of 0.22 or higher generates the DX center (a deeply localized level) in a band gap. As a result, noise of the QDIPs inevitably increases.

Embodiments of the present invention provides an infrared detector capable of achieving higher sensitivity with less noise.

First Configuration

According to an embodiment of the present invention, an infrared detector includes: a first contact layer; a second contact layer; a photoelectric conversion layer; a barrier layer; and an insertion layer. Each of the first contact layer and the second contact layer is doped with a dopant. The photoelectric conversion layer is placed between the first contact layer and the second contact layer, and includes a quantum layer and an intermediate layer. The barrier layer is placed between the photoelectric conversion layer and only one of the first contact layer or the second contact layer. The insertion layer is placed between, and in contact with, the photoelectric conversion layer and the one of the first contact layer or the second contact layer.

Second Configuration

In the first configuration, the intermediate layer and the insertion layer may be made of the same material.

Third Configuration

In the second configuration, the intermediate layer and the insertion layer may be made of GaAs.

Fourth Configuration

In any one of the first to third configurations, the barrier layer may be made of AlGaAs.

Fifth Configuration

In the fourth configuration, the AlGaAs may have an Al composition of 0.22 or higher.

Sixth Configuration

In any one of the first to fifth configurations, the insertion layer may have a thickness of 10 nm or more.

Seventh Configuration

In any one of the first to sixth configurations, the insertion layer may contain a dopant having a dopant concentration of 1×10¹⁷ cm⁻³ or lower.

Eighth Configuration

In the seventh configuration, the insertion layer may contain a dopant having a dopant concentration of 5×10¹⁵ cm⁻³ or lower.

Ninth Configuration

In any one of the first to eighth configurations, the one of the first contact layer or the second contact layer may be located on a substrate side.

Tenth Configuration

In any one of the first to ninth configurations, the dopant of one of the first contact layer or the second contact layer may be made of silicon.

An infrared detector of the present invention can achieve higher sensitivity with less noise.

### BRIEF DESCRIPTION OF THE DRAWINGS

FIG. 1 is a cross-sectional view of an infrared detector according to a first embodiment of the present invention;

FIGS. 2A-2E indicate a drawing of a first step illustrating a method for manufacturing the infrared detector in FIG. 1;

FIGS. 3F-3H indicate a drawing of a second step illustrating the method for manufacturing the infrared detector in FIG. 1;

FIGS. 4I-4J indicate a drawing of a third step illustrating the method for manufacturing the infrared detector in FIG. 1;

FIG. 5 is a drawing illustrating a band profile of the infrared detector in FIG. 1;

FIG. 6 is a drawing illustrating potential distributions, comparing cases with and without an insertion layer (GaAs) provided between a contact layer and a barrier layer;

FIG. 7 is a drawing illustrating a relationship between a current density of a dark current and an electric field of a quantum well region;

FIG. 8 is a drawing illustrating a relationship between a current density of a dark current and an electric field of a quantum well region;

FIG. 9 is a drawing illustrating a relationship between a current density of a dark current and an electric field of a quantum well region;

FIG. 10 is a cross-sectional view of an infrared detector according to a second embodiment of the present invention;

FIGS. 11A-11E indicate a drawing of a first step illustrating a method for manufacturing the infrared detector in FIG. 10;

FIGS. 12F-12H indicate a drawing of a second step illustrating the method for manufacturing the infrared detector in FIG. 10; and

FIGS. 13I-13J indicate a drawing of a third step illustrating the method for manufacturing the infrared detector in FIG. 10.

### DETAILED DESCRIPTION OF THE INVENTION

Embodiments of the present invention are described in detail below, with reference to the drawings. Note that identical reference signs are used to denote identical or substantially identical components, and the descriptions of the components shall not be repeated.

Embodiments of the present invention provides an infrared detector capable of achieving higher sensitivity with less noise. That is, the infrared detector described below is to overcome a challenge to satisfy both of incompatible issues; that is, high sensitivity and little noise. The challenge is conventionally a novel one that those skilled in the art have not been recognized.

### First Embodiment

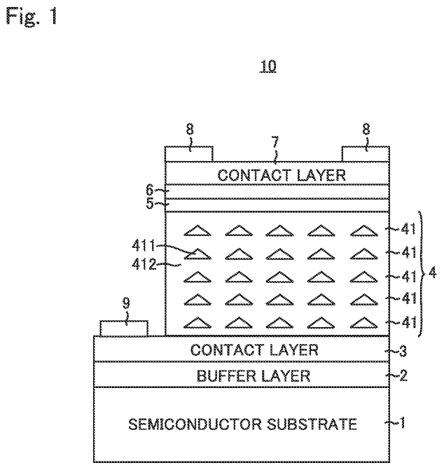

FIG. 1 is a cross-sectional view of an infrared detector according to a first embodiment of the present invention. With reference to FIG. 1, an infrared detector 10 according to the first embodiment of the present invention includes: a semiconductor substrate 1; a buffer layer 2; contact layers 3 and 7; a photoelectric conversion layer 4; a barrier layer 5; an insertion layer 6; and electrodes 8 and 9.

The buffer layer 2 is placed on and above a face of the semiconductor substrate 1. The contact layer 3 is placed on and above the buffer layer 2.

The photoelectric conversion layer 4 is placed on and above the contact layer 3. The barrier layer 5 is placed on and above the photoelectric conversion layer 4. The insertion layer 6 is placed on and above the barrier layer 5.

The contact layer 7 is placed on and above the insertion layer 6. The electrode 8 is placed on and above the contact layer 7. The electrode 9 is placed on and above the contact layer 3.

The semiconductor substrate 1 is made of, for example, semi-insulating GaAs. The buffer layer 2 is made of, for example, GaAs. The contact layer 3 is made of, for example, n⁺GaAs. The barrier layer 5 is made of AlₓGa₁₋ₓAs (x≥0.22).

The insertion layer 6 is made of, for example, GaAs. The contact layer 7 is made of, for example, n⁺GaAs. Each of the electrodes 8 and 9 is an n-type electrode, and made of, for example, AuGeNi/Au.

The photoelectric conversion layer 4 includes a plurality of quantum-dot layers 41. Each of the quantum-dot layers 41 includes: quantum dots 411 and an intermediate layer 412.

The quantum dots 411 are separated by the intermediate layer 412, and each made of, for example, InAs or InGaAs. The intermediate layer 412 is made of, for example, GaAs or AlGaAs.

The quantum dot 411 is shaped into a pyramid. For example, the quantum dot 411 has a height of 5 nm and a pyramid base of 25 nm. A spacing between the quantum dots 411 in the stacking direction is, for example, 50 nm.

Note that FIG. 1 illustrates five quantum dot layers 41. However, the number of the quantum dot layers 41 may commonly be two or more.

The buffer layer 2 has a thickness ranging, for example, from 100 nm to 500 nm. Each of the contact layers 3 and 7 has a thickness ranging, for example, from 100 nm to 1,000 nm, and has a dopant (e.g. Si) concentration of, for example, 1×10¹⁸ cm⁻³. The barrier layer 5 has a thickness of, for example, 40 nm.

The insertion layer 6 has a thickness of, for example, 20 nm. The insertion layer 6 may contain a dopant (e.g. Si) having a dopant concentration of 1×10¹⁷ cm⁻³ or lower, and, preferably, 5×10¹⁵ cm⁻³ or lower. Each of the electrodes 8 and 9 has a thickness ranging, for example, from 10 nm to 500 nm.

Note that, when the intermediate layer 412 of the infrared detector 10 is made of GaAs, the insertion layer 6 and the intermediate layer 412 are made of the same material.

A photoelectric conversion layer of a QDIP structure has a typical quantum-dot structure including InₓGa₁₋ₓAs (0≤x≤1) quantum dots on a GaAs substrate, and an Al_{y}Ga_{1-y}As (0≤y≤1) intermediate layer. Other than that, the photoelectric conversion layer has: a quantum-dot structure including InₓGa₁₋ₓAs (0≤x≤1) quantum dots on a GaAs substrate, and an In_{z}Ga_{1-z}P (0≤z≤1) intermediate layer; and a quantum-dot structure including InₓGa₁₋ₓAs (0≤x≤1) quantum dots on an InP substrate, and an InₚAl₁₋ₚAs (0≤p≤1) intermediate layer.

In the present application, the inventors pay attention to a photoelectric conversion layer having the typical quantum-dot structure including: InₓGa₁₋ₓAs (0≤x≤1) quantum dots on a GaAs substrate; and an Al_{y}Ga_{1-y}As (0≤y≤1) intermediate layer. In addition, the inventors pay attention to an infrared detector including a barrier layer (a single barrier layer) made of AlGaAs and placed only on one side of the photoelectric conversion layer.

In a concept of the single barrier layer, a high barrier is provided between the photoelectric conversion layer and only one of the contact layers. Such a structure makes it possible to reduce a dark current alone from the contact layer, without affecting transport of carriers (a photocurrent) produced by the quantum dots. As a result, the infrared detector can operate with high sensitivity under high temperature. Note that when a barrier layer is provided to each side of the photoelectric conversion layer, the photocurrent is inevitably reduced. However, the dark current can also be reduced, allowing the infrared detector to operate with high sensitivity under high temperature. Even if a barrier layer is provided to each side of the photoelectric conversion layer, an insertion layer additionally provided as seen in the present application has an advantageous effect of reducing a defect to be generated in the barrier layers. Hence, it is preferable to apply the features of the present application.

Other than that, in a typical infrared detector including a photoelectric conversion layer having the quantum-dot structure of InₓGa₁₋ₓAs (0≤x≤1) quantum dots, and an Al_{y}Ga_{1-y}As (0≤y≤1) intermediate layer, the intermediate layer may be made of AlGaAs having an Al composition of 0.22 or higher. Compared with a typical intermediate layer made of GaAs, the intermediate layer made of AlGaAs would reliably reduce a dark current. However, the latter intermediate layer would act as a barrier also for photoexcited carriers, inevitably resulting in a significant reduction in photocurrent. A voltage to be applied needs to be higher as AlGaAs whose Al composition is 0.22 or higher is thicker. Hence, the single barrier layer can exhibit favorable performance at low voltage.

Moreover, compared with typical GaAs, a material having a wide band gap is generally likely to deteriorate in quality. In the case of the single-barrier-layer structure, the thickness in the structure can only be that of the single barrier (e.g. 40 nm). Hence, the use of the material having a wide band gap is reduced to minimum, and the resulting quality of the infrared detector is high and favorable.

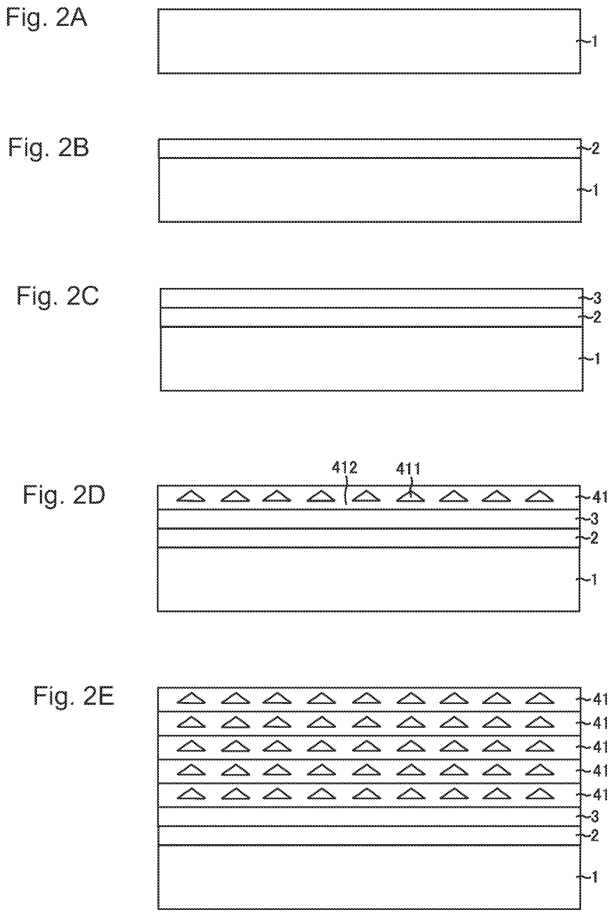

FIGS. 2A to 2E, FIGS. 3F to 3H and FIGS. 4I to 4J illustrate first to third steps showing a method for manufacturing the infrared detector 10 in FIG. 1.

With reference to FIG. 2A, when the manufacture of the detection unit 10 starts, the semiconductor substrate 1 made of semi-conductive GaAs is supported inside a molecular beam epitaxy (MBE) apparatus (a step (a) in FIG. 2A).

After that, the buffer layer 2 is formed on the semiconductor substrate 1 with the MBE at a growth temperature of 580° C. (a step (b) in FIG. 2B). Here, an example of the buffer layer 2 is a GaAs layer having a thickness of 200 nm. The formed buffer layer 2 can improve crystallinity of the photoelectric conversion layer 4 to be formed on the butter layer 2. The improvement in crystallinity makes it possible to provide the infrared detector with the photoelectric conversion layer 4 having sufficient photoreception efficiency.

After the step (b), the contact layer 3 is formed on the buffer layer 2 with the MBE (a step (c) in FIG. 2C). Here, an example of the contact layer 3 is an n⁺GaAs layer having a thickness of 1,000 nm.

After that, a quantum-dot layer 41 including the quantum dots 411 and the intermediate layer 412 is formed on the contact layer 3 with the MBE (a step (d) in FIG. 2D).

Here, the quantum dots 411 are formed with a technique called the Stranski-Krastanov (S-K) growth.

More specifically, a GaAs layer is crystal-grown as the intermediate layer 412. After that, the quantum dots 411 made of InAs are formed with a self-organizing mechanism. After that, the GaAs layer is crystal-grown as the intermediate layer 412 to form the quantum dots layer 41. Note that, in forming the quantum dots 411, the quantum dot layer 41 may be doped to be supplied with carriers. An example of the dopant is Si.

The step (d) is repeated, for example, five times, so that five quantum dots layers 41 are stacked on top of an other to form the photoelectric conversion layer 4 on the contact layer 3 (a step (e) in FIG. 2E).

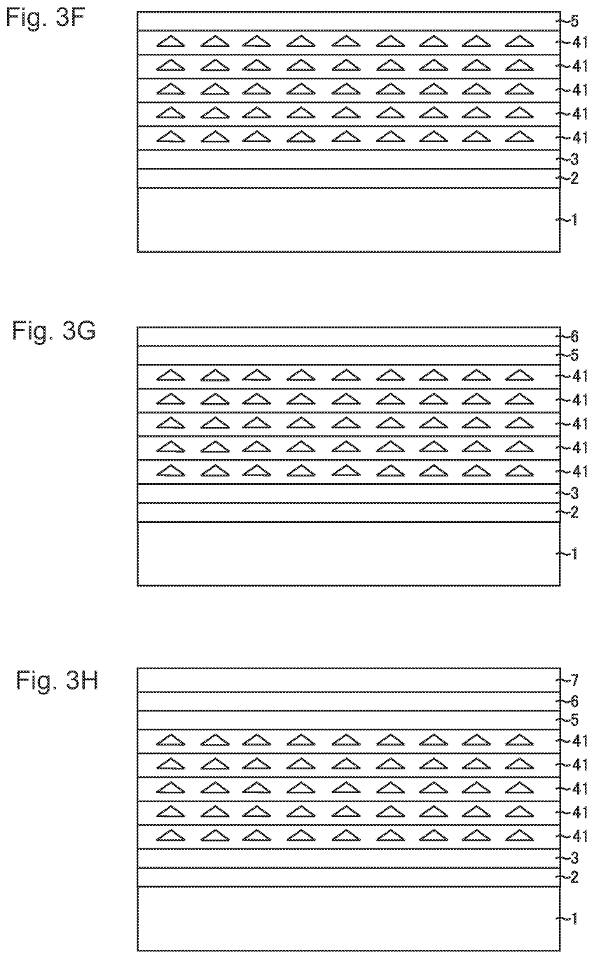

After the step (e) in FIG. 2E, the barrier layer 5 made of Al_{0.3}Ga_{0.7}As is formed on the photoelectric conversion layer 4 with the MBE (a step (f) in FIG. 3F). A growth temperature after the formation of the photoelectric conversion layer 4, including the growth temperature of the barrier layer 5, is set to 530° C. to keep the temperature from affecting the quantum dots.

After that, the insertion layer 6 made of GaAs is formed on the barrier layer 5 with the MBE (a step (g) in FIG. 3G).

After that, the contact layer 7 is formed on the insertion layer 6 with the MBE (a step (h) in FIG. 3H). Here, an example of the contact layer 7 is an n⁺GaAs layer crystal-grown to have a thickness of 500 nm. Hence, an n⁺in⁺ structure is formed.

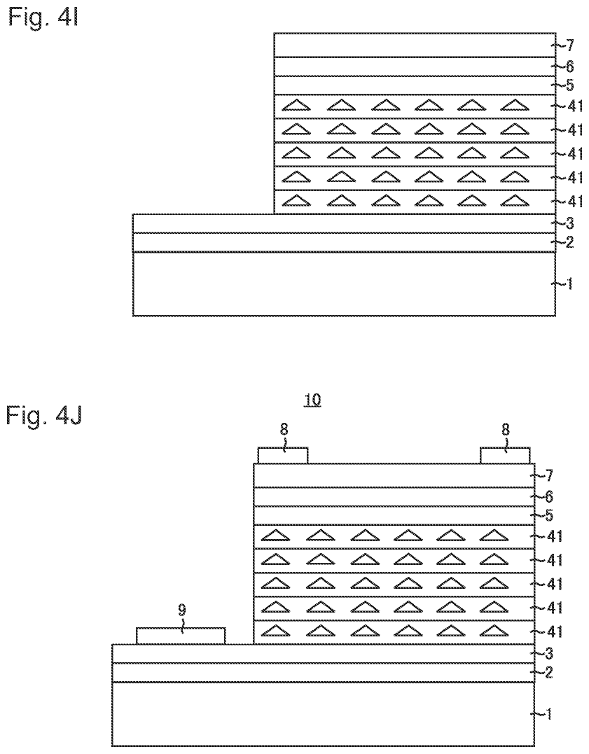

The stacked product is taken out of the MBE apparatus. With a photolithography technique and wet etching, the photoelectric conversion layer 4, the barrier layer 5, the insertion layer 6, and the contact layer 7 are partially removed (a step (i) in FIG. 4I). After that, the electrode 8 and the electrode 9 are respectively formed on the contact layer 7 and the contact layer 3. Hence, the infrared detector 10 is completed (a step (j) in FIG. 4J).

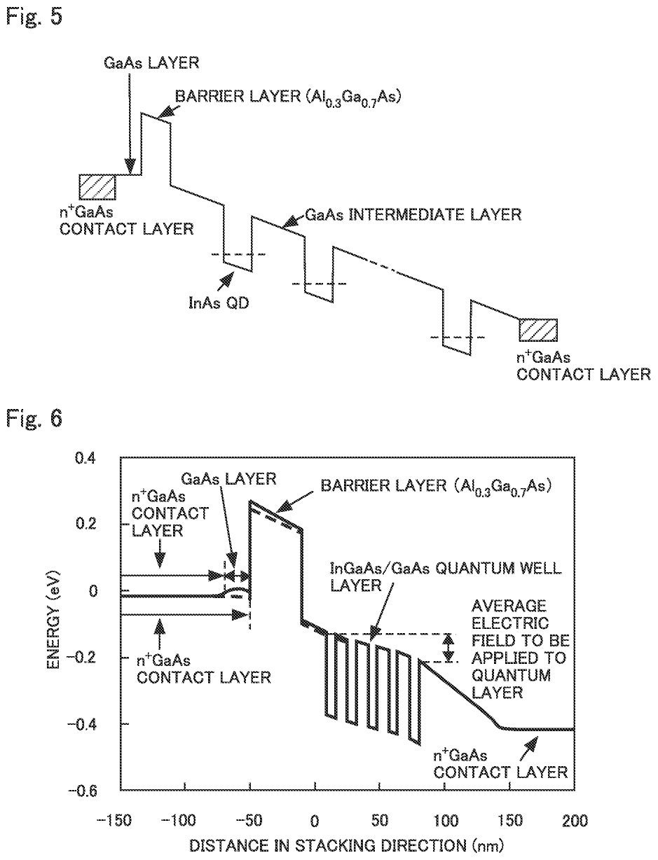

FIG. 5 is a drawing illustrating a band profile of the infrared detector 10 in FIG. 1. Note that the band profile in FIG. 5 illustrates a conduction band observed when a voltage is applied to the infrared detector 10.

With reference to FIG. 5, the photoelectric conversion layer, including quantum dots (QDs) made of InAs and an intermediate layer made of GaAs, has one side provided with an n⁺GaAs contact layer and an other side provided with a barrier layer made of Al_{0.3}Ga_{0.7}As.

An insertion layer made of GaAs is disposed in contact with the barrier layer, and the n⁺GaAs contact layer is disposed in contact with the insertion layer.

In the steps illustrated in FIGS. 2A to 2E, FIGS. 3F to 3H and FIGS. 4I to 4J for manufacturing the infrared detector 10, the barrier layer, the insertion layer, and the n⁺GaAs contact layer are stacked on top of an other in the stated order on the photoelectric conversion layer (see the steps (g) and (h) in FIGS. 3G and 3H).

As a result, the n⁺GaAs contact layer is formed on the insertion layer, making it possible to keep silicon (Si) atoms; that is, a dopant of the n⁺GaAs contact layer, from diffusing into the barrier layer during the formation of the n⁺GaAs contact layer. Moreover, the barrier layer can reduce a dark current of the infrared detector.

Such features keep a DX center from forming in the barrier layer, contributing to improvement in sensitivity, and reduction in noise, of the infrared detector 10.

Studied here using a device simulation were effects, of the insertion layer 6 inserted between the contact layer 7 and the barrier layer 5, on an average electric field to be applied to a dark current and a quantum layer.

More specifically, a Schrödinger-Poisson equation and a drift-diffusion current equation were solved by self-consistent calculation.

In order to study the effects of the inserted insertion layer (GaAs), a quantum well layer was given as the quantum layer for simplicity in the calculation.

Table 1 shows conditions of the calculation.

TABLE 1

| Device Structure | n⁺-n-n⁺ structure |
|---|---|
| Quantum Well Layer | Material: In_{0.5}Ga_{0.5}As Thickness: |
| | 7.5 nm |
| Intermediate Layer | Material: GaAs Thickness: 9 nm |
| Barrier Layer | Material: Al_{0.3}Ga_{0.7}As |
| | Thickness: 40 nm |
| Insertion Layer | Material: GaAs Thickness: 20 nm |
| Number of Quantum Well Layer | 5 |
| Concentration of Doping to | 1.3 × 10¹⁷ cm⁻³ |
| Quantum Well | |
| Operating Temperature | 200 K |
| Applied Voltage | 0 V to 1 V |

FIG. 6 is a drawing illustrating potential distributions, comparing cases with and without the insertion layer (GaAs) provided between the contact layer and the barrier layer. In FIG. 6, the vertical axis represents energy, and the horizontal axis represents a distance in the stacking direction. Moreover, the solid line represents a potential distribution when the insertion layer (GaAs) is inserted, and the dashed line represents a potential distribution when the insertion layer (GaAs) is not inserted.

With reference to FIG. 6, the insertion layer (GaAs) increases the potential barrier of the barrier layer. Moreover, even though the average electric field to be applied to the quantum layer (a well layer) does not significantly change regardless of a case with or without the insertion layer (GaAs), the dark current is 4 A/cm² when the insertion layer (GaAs) is inserted and is 11 A/cm² when the insertion layer (GaAs) is not inserted.

Accordingly, the study shows as a side benefit that the insertion layer (GaAs) inserted between the contact layer and the barrier layer can reduce the dark current. As a result, the infrared detector can operate with higher sensitivity under higher temperature.

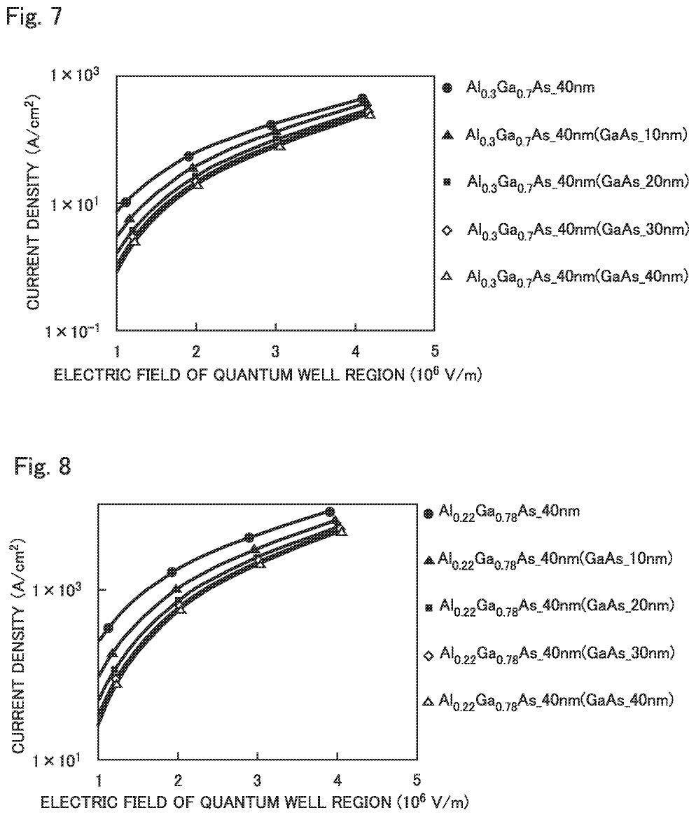

FIGS. 7 to 9 are drawings illustrating relationships between a current density of a dark current and an electric field of a quantum well region. In FIGS. 7 to 9, the vertical axis represents a current density, and the horizontal axis represents an electric field of a quantum well region.

In FIG. 7, the reference signs ● represent a relationship between an electric field of a quantum well region and a current density, using a barrier layer made of Al_{0.3}Ga_{0.7}As and having a thickness of 40 nm, but not using an insertion layer. The reference signs ▴ represent a relationship between an electric field of a quantum well region and a current density, using a GaAs layer (an insertion layer) having a thickness of 10 nm and a barrier layer made of Al_{0.3}Ga_{0.7}As and having a thickness of 40 nm. The reference signs ▪ represent a relationship between an electric field of a quantum well region and a current density, using a GaAs layer (an insertion layer) having a thickness of 20 nm and a barrier layer made of Al_{0.3}Ga_{0.7}As and having a thickness of 40 nm. The reference signs ⋄ represent a relationship between an electric field of a quantum well region and a current density, using a GaAs layer (an insertion layer) having a thickness of 30 nm and a barrier layer made of Al_{0.3}Ga_{0.7}As and having a thickness of 40 nm. The reference signs Δ represent a relationship between an electric field of a quantum well region and a current density, using a GaAs layer (an insertion layer) having a thickness of 40 nm and a barrier layer made of Al_{0.3}Ga_{0.7}As and having a thickness of 40 nm.

Moreover, in FIG. 8, the reference signs ● represent a relationship between an electric field of a quantum well region and a current density, using a barrier layer made of Al_{0.22}Ga_{0.78}As and having a thickness of 40 nm, but not using an insertion layer. The reference signs ▴ represent a relationship between an electric field of a quantum well region and a current density, using a GaAs layer (an insertion layer) having a thickness of 10 nm and a barrier layer made of Al_{0.22}Ga_{0.78}As and having a thickness of 40 nm. The reference signs ▪ represent a relationship between an electric field of a quantum well region and a current density, using a GaAs layer (an insertion layer) having a thickness of 20 nm and a barrier layer made of Al_{0.22}Ga_{0.78}As and having a thickness of 40 nm. The reference signs ⋄ represent a relationship between an electric field of a quantum well region and a current density, using a GaAs layer (an insertion layer) having a thickness of 30 nm and a barrier layer made of Al_{0.22}Ga_{0.78}As and having a thickness of 40 nm. The reference signs Δ represent a relationship between an electric field of the quantum well and a current density, using a GaAs layer (an insertion layer) having a thickness of 40 nm and a barrier layer made of Al_{0.22}Ga_{0.78}As and having a thickness of 40 nm.

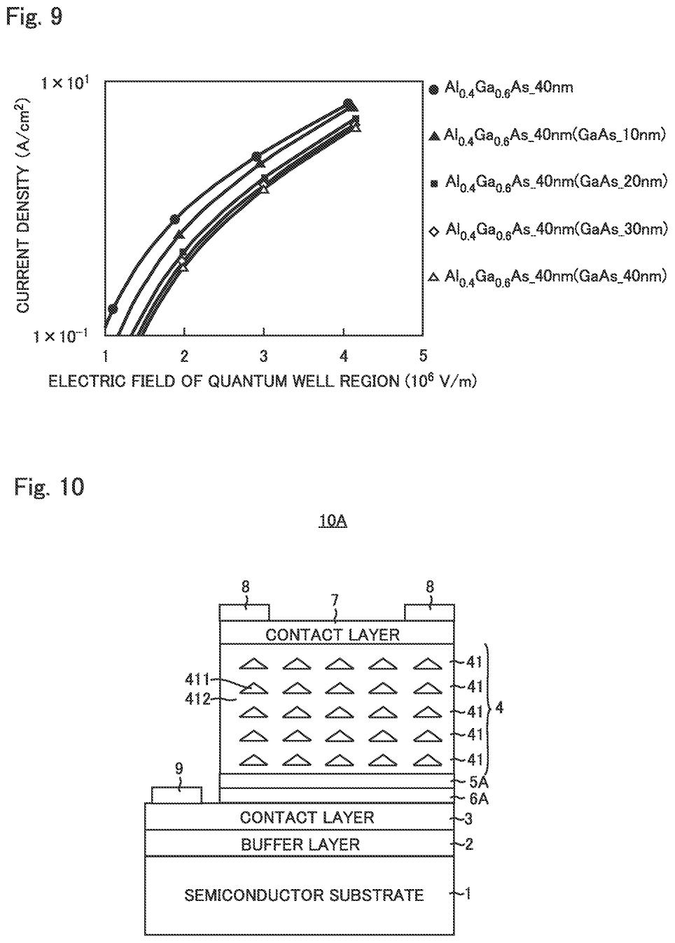

Moreover, in FIG. 9, the reference signs ● represent a relationship between an electric field of a quantum well region and a current density, using a barrier layer made of Al_{0.4}Ga_{0.6}As and having a thickness of 40 nm, but not using an insertion layer. The reference signs ▴ represent a relationship between an electric field of a quantum well region and a current density, using a GaAs layer (an insertion layer) having a thickness of 10 nm and a barrier layer made of Al_{0.4}a_{0.6}As and having a thickness of 40 nm. The reference signs ▪ represent a relationship between an electric field of a quantum well region and a current density, using a GaAs layer (an insertion layer) having a thickness of 20 nm and a barrier layer made of Al_{0.4}Ga_{0.6}As and having a thickness of 40 nm. The reference signs ⋄ represent a relationship between an electric field of a quantum well region and a current density, using a GaAs layer (an insertion layer) having a thickness of 30 nm and a barrier layer made of Al_{0.4}Ga_{0.6}As and having a thickness of 40 nm. The reference signs Δ represent a relationship between an electric field of a quantum well region and a current density, using a GaAs layer (an insertion layer) having a thickness of 40 nm and a barrier layer made of Al_{0.4}Ga_{0.6}As and having a thickness of 40 nm.

FIGS. 7 to 9 show that, when any one of Al_{0.22}Ga_{0.78}As, Al_{0.3}Ga_{0.7}As, and Al_{0.4}Ga_{0.6}As is used as the barrier layer, the current density of the dark current decreases in each electric field of the quantum well region as the thickness of the insertion layer (GaAs) increases. When the thickness of the insertion layer (GaAs) is 30 nm or more, the dark current is converged.

As can be seen, the insertion layer (GaAs) provided between the contact layer and the barrier layer can achieve an advantageous effect of reducing the dark current. This advantageous effect is not readily expected by those skilled in the art.

### Second Embodiment

FIG. 10 is a cross-sectional view of an infrared detector according to a second embodiment. With reference to FIG. 10, an infrared detector 10A according to the second embodiment is the infrared detector 10 illustrated in FIG. 1 whose barrier layer 5 and insertion layer 6 are replaced with a barrier layer 5A and an insertion layer 6A. Other features of the infrared detector 10A are the same as those of the infrared detector 10.

The insertion layer 6A is placed on and above the contact layer 3. The barrier layer 5A is placed on and above the insertion layer 6A.

In the infrared detector 10A, the photoelectric conversion layer 4 is placed on and above the barrier layer 5A, and the contact layer 7 is placed on and above the photoelectric conversion layer 4.

The barrier layer 5A is the same in material and thickness as the barrier layer 5 described above. The insertion layer 6A is the same in material and thickness as the insertion layer 6 described above.

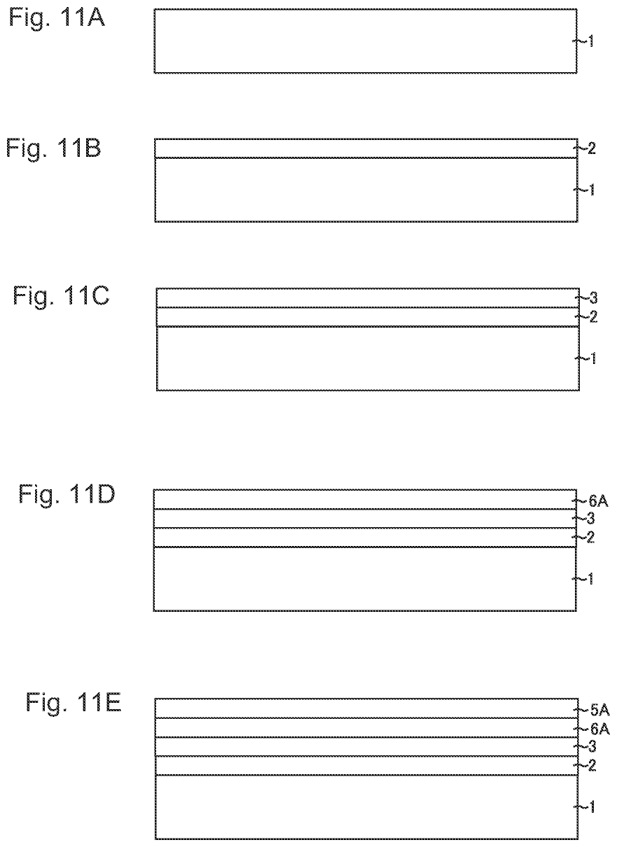

FIGS. 11A to 11E, FIGS. 12F to 12H and FIGS. 13I to 13J illustrate first to third steps showing a method for manufacturing the infrared detector 10A in FIG. 10.

With reference to FIGS. 11A to 11C, the manufacture of the infrared detector 10A starts. The same steps as the steps (a) to (c) illustrated in FIGS. 2A to 2C are sequentially carried out (steps (a) to (c) in FIGS. 11A to 11C).

After the step (c), the insertion layer 6A is formed on the contact layer 3 with the MBE (a step (d) in FIG. 11D).

After that, at a growth temperature of 580° C., the barrier layer 5A is formed on the insertion layer 6A with the MBE (a step (e) in FIG. 11E).

In manufacturing the infrared detector 10A, the barrier layer 5A is grown at a growth temperature higher than the growth temperature of the barrier layer 5 in the first embodiment (e.g. 530° C. in the first embodiment). Such a feature makes it possible to improve crystallinity of AlGaAs included in the barrier layer 5A, contributing to improvement in quality of AlGaAs.

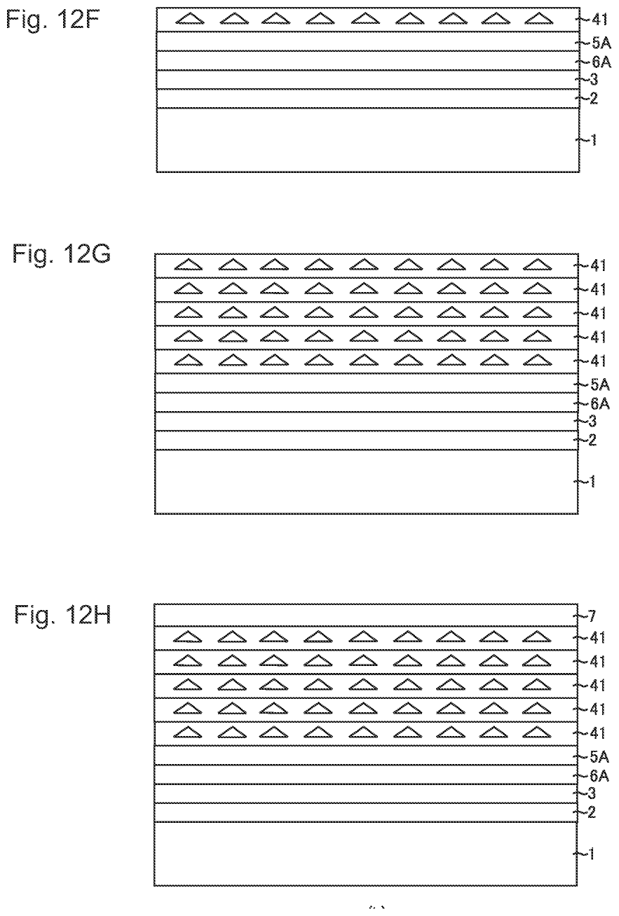

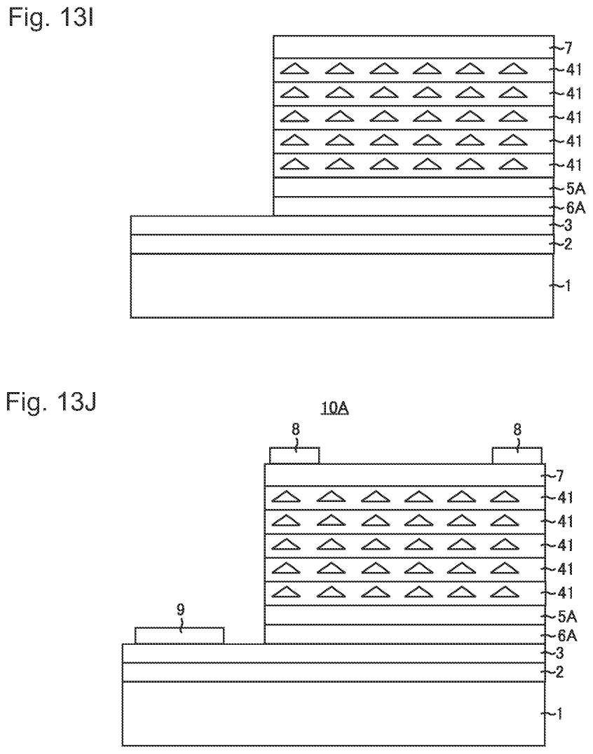

After the step (e) in FIG. 11E, the same steps as the steps (d) and (e) in FIGS. 2D and 2E are sequentially carried out. The photoelectric conversion layer 4 including five quantum-dot layers 41 is formed on the barrier layer 5A (steps (f) and (g) in FIGS. 12F and 12G).

After the step (g) in FIG. 12G, the contact layer 7 is formed on the photoelectric conversion layer 4 with the MBE (a step (h) in FIG. 12H). Here, an example of the contact layer 7 is an n⁺GaAs layer crystal-grown to have a thickness of 500 nm. Hence, an n⁺in+ structure is formed.

The stacked product is taken out of the MBE apparatus. With a photolithography technique and wet etching, the photoelectric conversion layer 4, the barrier layer 5A, the insertion layer 6A, and the contact layer 7 are partially removed (a step (i) in FIG. 13I). After that, the electrode 8 and the electrode 9 are respectively formed on the contact layer 7 and the contact layer 3. Hence, the infrared detector 10A is completed (a step (j) in FIG. 13J).

In the method for manufacturing the infrared detector 10A described above, the growth temperature in forming the barrier layer 5A is set higher than that in forming the barrier layer 5 according to the first embodiment. Hence, even though the infrared detector 10A is susceptible to diffusion of a dopant (e.g. Si) from the contact layer 3, the insertion layer 6A between the contact layer 3 and the barrier layer 5A can reduce the influence of the diffusion of the dopant (e.g. Si) from the contact layer 3.

Such a feature keeps from forming a defect level in the barrier layer 5A, making it possible to reduce a dark current. As a result, the infrared detector 10A can enjoy the same advantageous effects as those of the infrared detector 10 according to the first embodiment.

Other descriptions in the second embodiment are the same as those in the first embodiment.

The above first embodiment describes the infrared detector 10 in which the barrier layer 5 is placed above the photoelectric conversion layer 4, and the insertion layer 6 is inserted between the barrier layer 5 and the contact layer 7.

Alternatively, the second embodiment describes the infrared detector 10A in which the barrier layer 5A is placed below the photoelectric conversion layer 4, and the insertion layer 6A is inserted between the contact layer 3 and the barrier layer 5A.

Hence, an infrared detector according to the embodiments of the present invention includes: a first contact layer doped with a dopant; a second contact layer doped with a dopant; a photoelectric conversion layer placed between the first contact layer and the second contact layer, and including a quantum layer and an intermediate layer; a barrier layer (i) placed between the photoelectric conversion layer and only one of the first contact layer or the second contact layer, and (ii) made of AlGaAs having an Al composition of 0.22 or higher; and an insertion layer placed between, and in contact with, the barrier layer and the one of the first contact layer or the second contact layer.

Thanks to such features, the insertion layer keeps the dopant of the contact layer from diffusing into the barrier layer, making it possible to reduce a dark current. Hence, the infrared detector can achieve high sensitivity with little noise.

The embodiments disclosed herewith are examples in all respects, and shall not be interpreted to be limitative. The scope of the present invention is intended to be disclosed not in the above embodiments, but in the claims. All the modifications equivalent to the features of, and within the scope of, the claims are to be included in the scope of the present invention. While there have been described what are at present considered to be certain embodiments of the invention, it will be understood that various modifications may be made thereto, and it is intended that the appended claims cover all such modifications as fall within the true spirit and scope of the invention.

The present invention is applicable to an infrared detector.

What is claimed is:

1. An infrared detector, comprising:
a first contact layer doped with a dopant;
a second contact layer doped with a dopant;
a photoelectric conversion layer placed between the first contact layer and the second contact layer, and including a quantum layer and an intermediate layer;
a barrier layer placed between the photoelectric conversion layer and at least one of the first contact layer or the second contact layer; and
an insertion layer placed at least one of (i) between, and in contact with, the barrier layer and the first contact layer, or (ii) between, and in contact with, the barrier layer and the second contact layer.

2. The infrared detector according to claim 1, wherein
the intermediate layer and the insertion layer are made of the same material.

3. The infrared detector according to claim 2, wherein
the intermediate layer and the insertion layer are made of gallium arsenide.

4. The infrared detector according to claim 1, wherein
the barrier layer is made of aluminium gallium arsenide.

5. The infrared detector according to claim 4, wherein
the aluminium gallium arsenide has an aluminium composition of 0.22 or higher.

6. The infrared detector according to claim 1, wherein
the insertion layer has a thickness of 10 nm or more.

7. The infrared detector according to claim 6, wherein
the insertion layer has a thickness of 30 nm or more.

8. The infrared detector according to claim 1, wherein
the insertion layer contains a dopant having a dopant concentration of 1×10¹⁷ cm³ or lower.

9. The infrared detector according to claim 8, wherein
the insertion layer contains the dopant having a dopant concentration of 5×10¹⁵ cm⁻³ or lower.

10. The infrared detector according to claim 1, wherein
the dopant of at least one of the first contact layer or the second contact layer is made of silicon.

11. The infrared detector according to claim 1, wherein
the barrier layer is placed between the photoelectric conversion layer and only one of the first contact layer or the second contact layer.

12. The infrared detector according to claim 11, wherein
the one of the first contact layer or the second contact layer is located on a substrate side.

13. The infrared detector according to claim 1, wherein
the barrier layer includes two barrier layers each placed one of (i) between the photoelectric conversion layer and the first contact layer, and (ii) between the photoelectric conversion layer and the second contact layer, and
the insertion layer is placed at least one of (i) between, and in contact with, the barrier layer and the first contact layer, or (ii) between, and in contact with, the barrier layer and the second contact layer.

14. The infrared detector according to claim 2, wherein
the barrier layer is made of aluminium gallium arsenide.

15. The infrared detector according to claim 14, wherein
the aluminium gallium arsenide has an aluminium composition of 0.22 or higher.

16. The infrared detector according to claim 2, wherein
the insertion layer has a thickness of 10 nm or more.

17. The infrared detector according to claim 2, wherein
the insertion layer contains a dopant having a dopant concentration of 1×10¹⁷ cm³ or lower.

18. The infrared detector according to claim 2, wherein
the barrier layer is placed between the photoelectric conversion layer and only one of the first contact layer or the second contact layer, and
the one of the first contact layer or the second contact layer is located on a substrate side.

19. The infrared detector according to claim 2, wherein
the dopant of at least one of the first contact layer or the second contact layer is made of silicon.

20. The infrared detector according to claim 2, wherein
the barrier layer includes two barrier layers each placed one of (i) between the photoelectric conversion layer and the first contact layer, and (ii) between the photoelectric conversion layer and the second contact layer, and
the insertion layer is placed at least one of (i) between, and in contact with, the barrier layer and the first contact layer, or (ii) between, and in contact with, the barrier layer and the second contact layer.
